(19) United States
(12) Patent Application Publication
(10) Pub. No.: US 2026/0196257 A1
(43) Pub. Date: Jul. 9, 2026

(54) MULTIPLE PASS TRAINING PROCEDURES

(71) Applicant: Micron Technology, Inc., Boise, ID (US)

(72) Inventor: Marcos Alvarez GONZALEZ, München (DE)

(21) Appl. No.: 19/392,464

(22) Filed: Nov. 18, 2025

Related U.S. Application Data
(60) Provisional application No. 63/743,405, filed on Jan. 9, 2025.

(51) Int. Cl. G11C 7/22; G11C 7/10; H03L 7/081

(52) U.S. Cl. CPC G11C 7/222; G11C 7/1093; H03L 7/0818

(57) ABSTRACT

In some implementations, a host system may perform a first training procedure to determine a first one or more signaling parameters associated with communicating signals between the host system and a memory device. The host system may provide, to the memory device, an alignment command to identify a phase relationship between a host system clock signal and a memory apparatus clock signal. The host system may perform, based on the phase relationship, a second training procedure to determine a second one or more signaling parameters associated with communicating signals between the host system and the memory device.

### CROSS-REFERENCE TO RELATED APPLICATION

This Patent application claims priority to U.S. Provisional Patent Application No. 63/743,405, filed on Jan. 9, 2025, entitled “MULTIPLE PASS TRAINING PROCEDURES,” and assigned to the assignee hereof. The disclosure of the prior Application is considered part of and is incorporated by reference into this Patent Application.

### TECHNICAL FIELD

The present disclosure generally relates to memory devices, memory device operations, and, for example, to multiple pass training procedures.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, an electronic device may write to, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), holographic RAM (HRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source.

### BRIEF DESCRIPTION OF THE DRAWINGS

FIG. 1 is a diagram illustrating an example system capable of multiple pass training procedures.

FIG. 2 is a diagram illustrating an example of a timing diagram that supports multiple pass training procedures.

FIG. 3 is a diagram illustrating an example of a timing diagram that supports multiple pass training procedures.

FIGS. 4A through 4C are diagrams of an example of multiple pass training procedures.

FIG. 5 is a flowchart of an example method associated with multiple pass training procedures.

FIG. 6 is a flowchart of an example method associated with multiple pass training procedures.

### DETAILED DESCRIPTION

Some systems, such as a host system in communication with one or more graphics double data rate (GDDR) memory systems, one or more dynamic random access memory (DRAM) systems, and/or one or more synchronous graphics random access memory (SGRAM) systems, among other examples, may communicate data at a relatively high transfer speed (e.g., a rate at which data is communicated between a memory apparatus and the host system). To achieve such transfer speeds, these systems may utilize higher clock speeds, which may reduce the time window available for decoding data signals. This reduction in the time window may increase the likelihood of introducing errors into the data signals by reducing the integrity of the data signals. To improve the likelihood of correctly interpreting such data signals, a host system and/or a memory system may perform one or more training procedures, such as during a command bus training (CBT) mode. These procedures may include the memory apparatus sampling signals transferred via a command bus. The memory apparatus may return the sampled values to the host system for feedback adjustments.

Some systems may implement an alignment command after performing the training procedures. An alignment command may align an initial phase of a host system clock signal with an initial phase of the memory apparatus clock signal. However, if the alignment command causes such clock signals to shift, the previously established training parameters may become invalid. For example, when the alignment command shifts the clock signals, a phase relationship initially used to optimize the timing adjustments may be altered. Thus, the sampling positions determined during the initial training procedures may no longer correspond to the same points on the clock cycle.

Some implementations described herein enable multiple pass training procedures. For example, a host system may perform a coarse training procedure to one or more coarse signaling parameters used to communicate signals between the host system and a memory apparatus. The one or more coarse signaling parameters may include one or more approximately uniform timing intervals for a strobe signal. Because the host system may configure the timing intervals to be uniform, the coarse training procedure may be relatively resource inexpensive (e.g., may use relatively few time, signaling, and/or processing resources). After the coarse training procedure, the host system may communicate (e.g., using the one or more coarse signaling parameters) an alignment command to identify a phase relationship between a host system clock signal and a memory apparatus clock signal. After communicating the alignment command, the host system may perform a fine training procedure to identify one or more fine signaling parameters. The fine training procedure may include independently adjusting the timing intervals for clock phases, which may account for misalignments introduced by the alignment command.

As a result, by performing a multiple pass training procedure as described herein, the host system and/or the memory apparatus may reduce the likelihood of misalignment between the clock signals of the host system and the memory apparatus, thereby improving the reliability and/or accuracy of data communication. For example, by performing the coarse training procedure before issuing the alignment command, the host system may establish an initial approximate alignment for strobe signals and/or command signals. The approximate alignment may provide sufficient signal integrity to allow the host system to issue the alignment command. Additionally, by performing the fine training procedure after issuing the alignment command, the host system may determine improved signaling parameters without the risk of misalignment due to a subsequent alignment command.

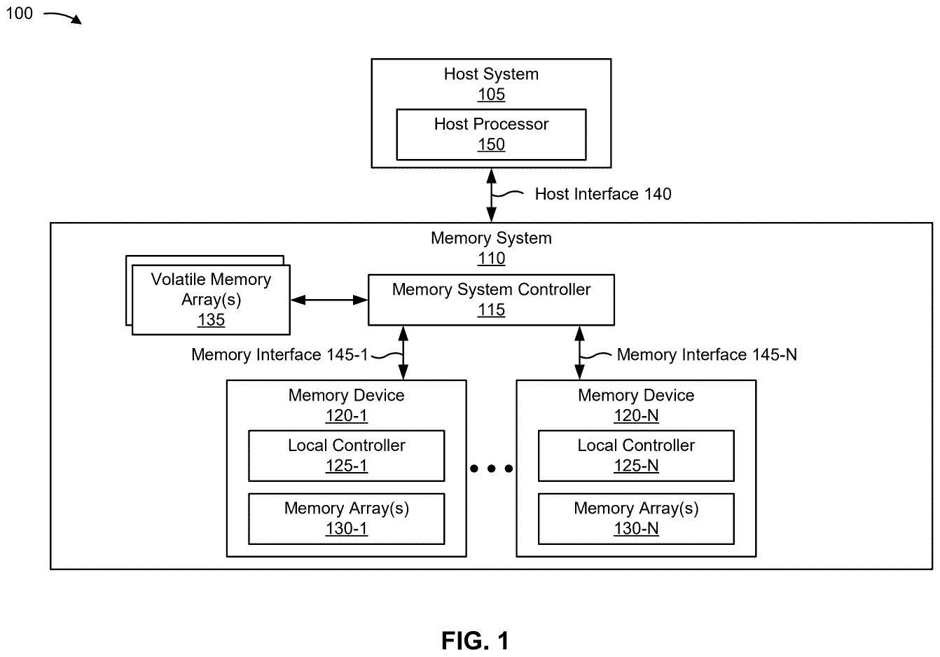

FIG. 1 is a diagram illustrating an example system 100 capable of multiple pass training procedures. The system 100 may include one or more devices, apparatuses, and/or components for performing operations described herein. For example, the system 100 may include a host system 105 and a memory system 110. The memory system 110 may include a memory system controller 115 and one or more memory devices 120, shown as memory devices 120-1 through 120-N (where N≥1). A memory device may include a local controller 125 and one or more memory arrays 130. The host system 105 may communicate with the memory system 110 (e.g., the memory system controller 115 of the memory system 110) via a host interface 140. The memory system controller 115 and the memory devices 120 may communicate via respective memory interfaces 145, shown as memory interfaces 145-1 through 145-N (where N≥ 1).

The system 100 may be any electronic device configured to store data in memory. For example, the system 100 may be a computer, a mobile phone, a wired or wireless communication device, a network device, a server, a device in a data center, a device in a cloud computing environment, a vehicle (e.g., an automobile or an airplane), and/or an Internet of Things (IoT) device. The host system 105 may include a host processor 150. The host processor 150 may include one or more processors configured to execute instructions and store data in the memory system 110. For example, the host processor 150 may include a central processing unit (CPU), a graphics processing unit (GPU), a field-programmable gate array (FPGA), an application-specific integrated circuit (ASIC), and/or another type of processing component.

The memory system 110 may be any electronic device or apparatus configured to store data in memory. For example, the memory system 110 may be a hard drive, a solid-state drive (SSD), a flash memory system (e.g., a NAND flash memory system or a NOR flash memory system), a universal serial bus (USB) drive, a memory card (e.g., a secure digital (SD) card), a secondary storage device, a non-volatile memory express (NVMe) device, an embedded multimedia card (eMMC) device, a dual in-line memory module (DIMM), and/or a random-access memory (RAM) device, such as a dynamic RAM (DRAM) device or a static RAM (SRAM) device.

The memory system controller 115 may be any device configured to control operations of the memory system 110 and/or operations of the memory devices 120. For example, the memory system controller 115 may include control logic, a memory controller, a system controller, an ASIC, an FPGA, a processor, a microcontroller, and/or one or more processing components. In some implementations, the memory system controller 115 may communicate with the host system 105 and may instruct one or more memory devices 120 regarding memory operations to be performed by those one or more memory devices 120 based on one or more instructions from the host system 105. For example, the memory system controller 115 may provide instructions to a local controller 125 regarding memory operations to be performed by the local controller 125 in connection with a corresponding memory device 120.

A memory device 120 may include a local controller 125 and one or more memory arrays 130. In some implementations, a memory device 120 includes a single memory array 130. In some implementations, each memory device 120 of the memory system 110 may be implemented in a separate semiconductor package or on a separate die that includes a respective local controller 125 and a respective memory array 130 of that memory device 120. The memory system 110 may include multiple memory devices 120.

A local controller 125 may be any device configured to control memory operations of a memory device 120 within which the local controller 125 is included (e.g., and not to control memory operations of other memory devices 120). For example, the local controller 125 may include control logic, a memory controller, a system controller, an ASIC, an FPGA, a processor, a microcontroller, and/or one or more processing components. In some implementations, the local controller 125 may communicate with the memory system controller 115 and may control operations performed on a memory array 130 coupled with the local controller 125 based on one or more instructions from the memory system controller 115. As an example, the memory system controller 115 may be an SSD controller, and the local controller 125 may be a NAND controller.

A memory array 130 may include an array of memory cells configured to store data. For example, a memory array 130 may include a non-volatile memory array (e.g., a NAND memory array or a NOR memory array) or a volatile memory array (e.g., an SRAM array or a DRAM array). In some implementations, the memory system 110 may include one or more volatile memory arrays 135. A volatile memory array 135 may include an SRAM array and/or a DRAM array, among other examples. The one or more volatile memory arrays 135 may be included in the memory system controller 115, in one or more memory devices 120, and/or in both the memory system controller 115 and one or more memory devices 120. In some implementations, the memory system 110 may include both non-volatile memory capable of maintaining stored data after the memory system 110 is powered off and volatile memory (e.g., a volatile memory array 135) that requires power to maintain stored data and that loses stored data after the memory system 110 is powered off. For example, a volatile memory array 135 may cache data read from or to be written to non-volatile memory, and/or may cache instructions to be executed by a controller of the memory system 110.

The host interface 140 enables communication between the host system 105 (e.g., the host processor 150) and the memory system 110 (e.g., the memory system controller 115). The host interface 140 may include, for example, a Small Computer System Interface (SCSI), a Serial-Attached SCSI (SAS), a Serial Advanced Technology Attachment (SATA) interface, a Peripheral Component Interconnect Express (PCIe) interface, an NVMe interface, a USB interface, a Universal Flash Storage (UFS) interface, an eMMC interface, a double data rate (DDR) interface, and/or a DIMM interface.

The memory interface 145 enables communication between the memory system 110 and the memory device 120. The memory interface 145 may include a non-volatile memory interface (e.g., for communicating with non-volatile memory), such as a NAND interface or a NOR interface. Additionally, or alternatively, the memory interface 145 may include a volatile memory interface (e.g., for communicating with volatile memory), such as a DDR interface.

Although the example memory system 110 described above includes a memory system controller 115, in some implementations, the memory system 110 does not include a memory system controller 115. For example, an external controller (e.g., included in the host system 105) and/or one or more local controllers 125 included in one or more corresponding memory devices 120 may perform the operations described herein as being performed by the memory system controller 115. Furthermore, as used herein, a “controller” may refer to the memory system controller 115, a local controller 125, or an external controller. In some implementations, a set of operations described herein as being performed by a controller may be performed by a single controller. For example, the entire set of operations may be performed by a single memory system controller 115, a single local controller 125, or a single external controller. Alternatively, a set of operations described herein as being performed by a controller may be performed by more than one controller. For example, a first subset of the operations may be performed by the memory system controller 115 and a second subset of the operations may be performed by a local controller 125. Furthermore, the term “memory apparatus” may refer to the memory system 110 or a memory device 120, depending on the context.

A controller (e.g., the memory system controller 115, a local controller 125, or an external controller) may control operations performed on memory (e.g., a memory array 130), such as by executing one or more instructions. For example, the memory system 110 and/or a memory device 120 may store one or more instructions in memory as firmware, and the controller may execute those one or more instructions. Additionally, or alternatively, the controller may receive one or more instructions from the host system 105 and/or from the memory system controller 115, and may execute those one or more instructions. In some implementations, a non-transitory computer-readable medium (e.g., volatile memory and/or non-volatile memory) may store a set of instructions (e.g., one or more instructions or code) for execution by the controller. The controller may execute the set of instructions to perform one or more operations or methods described herein. In some implementations, execution of the set of instructions, by the controller, causes the controller, the memory system 110, and/or a memory device 120 to perform one or more operations or methods described herein. In some implementations, hardwired circuitry is used instead of or in combination with the one or more instructions to perform one or more operations or methods described herein. Additionally, or alternatively, the controller may be configured to perform one or more operations or methods described herein. An instruction is sometimes called a “command.”

For example, the controller (e.g., the memory system controller 115, a local controller 125, or an external controller) may transmit signals to and/or receive signals from memory (e.g., one or more memory arrays 130) based on the one or more instructions, such as to transfer data to (e.g., write or program), to transfer data from (e.g., read), to erase, and/or to refresh all or a portion of the memory (e.g., one or more memory cells, pages, sub-blocks, blocks, or planes of the memory). Additionally, or alternatively, the controller may be configured to control access to the memory and/or to provide a translation layer between the host system 105 and the memory (e.g., for mapping logical addresses to physical addresses of a memory array 130). In some implementations, the controller may translate a host interface command (e.g., a command received from the host system 105) into a memory interface command (e.g., a command for performing an operation on a memory array 130).

In some implementations, one or more systems, devices, apparatuses, components, and/or controllers of FIG. 1 may include a host system configured to: perform a first training procedure to determine a first one or more signaling parameters associated with communicating signals between a host system and a memory device; provide, to the memory device, an alignment command to identify a phase relationship between a host system clock signal and a memory apparatus clock signal; and perform, based on the phase relationship, a second training procedure to determine a second one or more signaling parameters associated with communicating signals between the host system and the memory device.

In some implementations, one or more systems, devices, apparatuses, components, and/or controllers of FIG. 1 may include a host system configured to: determine a first one or more strobe intervals based on performing a coarse training procedure for a memory device; provide, to the memory device and using the first one or more strobe intervals, an alignment command to identify a phase relationship between a host system clock signal and a memory apparatus clock signal; and determine, using the phase relationship, a second one or more strobe intervals based on performing a fine training procedure for the memory device.

In some implementations, one or more systems, devices, apparatuses, components, and/or controllers of FIG. 1 may be configured to perform a first training procedure to determine a first one or more signaling parameters associated with communicating signals between a host system and a memory device; provide, to the memory device, an alignment command to identify a phase relationship between a host system clock signal and a memory apparatus clock signal; and perform, based on the phase relationship, a second training procedure to determine a second one or more signaling parameters associated with communicating signals between the host system and the memory device.

In some implementations, one or more systems, devices, apparatuses, components, and/or controllers of FIG. 1 may be configured to determine a first one or more strobe intervals based on performing a coarse training procedure for a memory device; provide, using the first one or more strobe intervals, an alignment command to identify a phase relationship between a host system clock signal and a memory apparatus clock signal; and determine, using the phase relationship, a second one or more strobe intervals based on performing a fine training procedure for the memory device.

The number and arrangement of components shown in FIG. 1 are provided as an example. In practice, there may be additional components, fewer components, different components, or differently arranged components than those shown in FIG. 1. Furthermore, two or more components shown in FIG. 1 may be implemented within a single component, or a single component shown in FIG. 1 may be implemented as multiple, distributed components. Additionally, or alternatively, a set of components (e.g., one or more components) shown in FIG. 1 may perform one or more operations described as being performed by another set of components shown in FIG. 1.

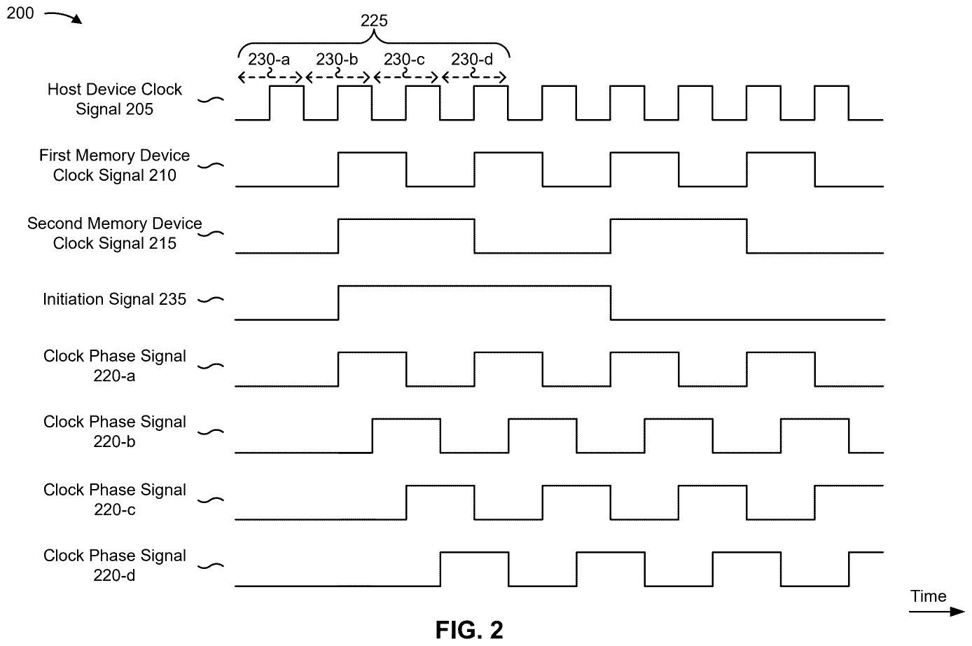

FIG. 2 is a diagram illustrating an example of a timing diagram 200 that supports multiple pass training procedures. The timing diagram 200 may illustrate timing aspects of signals communicated over and/or associated with one or more channels of an interface between a host system, such as the host system 105, and a memory apparatus, such as the memory system 110 and/or a memory device 120. For example, the timing diagram 200 may illustrate a host system clock signal 205 and one or more memory apparatus clock signals.

The host system may generate the host system clock signal 205 (e.g., using clock generation circuitry). The host system may provide the host system clock signal 205 to the memory apparatus, such as by transmitting the host system clock signal 205 to the memory apparatus using a channel (e.g., a clock pin on the host interface 140). In some implementations, the host system clock signal 205 may form a differential clock signal. For example, the host system clock signal 205 may include a first clock signal and a second clock signal that is shifted in phase by 180 degrees (e.g., by half of the period of the host system clock signal 205).

In some examples, the memory apparatus may generate one or more memory apparatus clock signals using the host system clock signal 205. For example, the memory apparatus may generate a base clock signal 210 having a base frequency (e.g., a frequency one quarter of the frequency of the host system clock signal 205). Further, the memory apparatus may generate an intermediate clock signal 215 having an intermediate clock frequency that is double the base frequency. In some implementations, the base clock signal 210 and/or the intermediate clock signal 215 may be examples of a multi-phase clock signal. As described herein, “multi-phase clock signal” refers to a group of clock signals having the same frequency, in which each clock signal is associated with a different phase of the multi-clock signal. For example, the intermediate clock signal 215 may include a first clock phase signal 220-a (e.g., a first phase), a second clock phase signal 220-b (e.g., a second phase) shifted in phase by 90 degrees (e.g., by one quarter of the period of the intermediate clock signal 215), a third clock phase signal 220-c (e.g., a third phase) shifted in phase by 180 degrees (e.g., by one half of the period of the intermediate clock signal 215), and a fourth clock phase signal 220-d (e.g., a fourth phase) shifted in phase by 270 degrees (e.g., by three quarters of the period of the intermediate clock signal 215).

The host system clock signal 205 may be organized according to a command interval 225. The command interval 225 may establish one or more command boundaries from which the host system and/or the memory apparatus may interpret commands. For example, a command interval 225 may include a sequence of clock cycles 230, such as a clock cycle 230-a, a clock cycle 230-b, a clock cycle 230-c, and a clock cycle 230-d. The host system may organize commands communicated to the memory apparatus (e.g., using a command/address bus that may include one or more command/address pins of the host interface 140) according to one or more command intervals 225. For example, the host system may transmit one or more first bits of a command during the clock cycle 230-a, may transmit one or more second bits of the command during the clock cycle 230-b, may transmit one or more third bits of the command during the clock cycle 230-c, and may transmit one or more fourth bits of the command during the clock cycle 230-d.

In some examples, the memory apparatus may interpret the command using the intermediate clock signal 215. For example, the memory apparatus may be configured to sample command signals (e.g., signals present on the command/address bus) at respective rising edges of the clock phase signals 220. The memory apparatus may decode the sampled signals to identify the transmitted data. In some implementations, the memory apparatus may be configured to interpret data sampled at the rising edge of the clock phase signal 220-a as corresponding to the clock cycle 230-a, interpret data sampled at the rising edge of the clock phase signal 220-b as corresponding to the clock cycle 230-b, interpret data sampled at the rising edge of the clock phase signal 220-c as corresponding to the clock cycle 230-c, and interpret data sampled at the rising edge of the clock phase signal 220-d as corresponding to the clock cycle 230-d. Additionally, or alternatively, the memory apparatus may be configured to interpret signals (e.g., signals communicated using a data bus) using a strobe signal. For example, the memory apparatus may be configured to sample data signals (e.g., signals present on the data bus) at respective rising edges of the strobe signal.

However, in some examples, the intermediate clock signal 215 and/or the strobe signal may be misaligned from the host system clock signal 205. For example, when the host system and memory apparatus initially power on, the host system may provide the host system clock signal 205. Additionally, the host system may provide a start signal 235 to indicate that the memory apparatus is to initiate the one or more memory apparatus clock signals (e.g., the base clock signal 210 and/or the intermediate clock signal 215). However, in some examples, the start signal 235 may not align with the initial phase of a command interval 225 (e.g., may not align with the clock cycle 230-a) of the host system clock signal 205. Accordingly, as illustrated in FIG. 2, the rising edge of the clock phase signal 220-a may not align with the rising edge of the clock cycle 230-a. This misalignment may cause the memory apparatus to be unable to interpret certain commands from the host system.

To address the misalignment, the host system may issue an alignment command, such as a command start point (CSP) command. The alignment command may indicate that the memory apparatus and/or the host system is to identify a phase relationship between the host system clock signal 205 and the intermediate clock signal 215. As described herein, a phase relationship between the host system clock signal 205 and the intermediate clock signal 215 is a phase offset (e.g., an amount of time, a duration, a quantity of clock cycles) between an initial phase of the host system clock signal 205 (e.g., the rising edge of the clock cycle 230-a) and an initial phase of the intermediate clock signal 215 (e.g., the rising edge of the clock phase signal 220-a). In some cases, the phase relationship may be represented as a value indicating a quantity of clock cycles (e.g., of the host system clock signal 205) between the host system clock signal 205 and the intermediate clock signal 215. For example, the phase relationship as illustrated in FIG. 2 may be one (1) clock cycle. In some implementations, the host system may store a value indicating the phase relationship. Additionally, or alternatively, the memory apparatus may store the phase relationship.

To issue the alignment command, the host system may transmit a data pattern over the command/address bus. Table 1 shows an example data pattern that may include one or more signal states transmitted over respective pins of the command/address bus during respective clock cycles 230. Pins of the command/address bus may be denoted as CA. A signal state may be a high state (denoted as H), corresponding to a high voltage level, or may be a low state (denoted as L), corresponding to a low voltage state.

TABLE 1

| Clock Cycle | CA0 | CA1 | CA2 | CA3 | CA4 |
|---|---|---|---|---|---|
| 230-a | H | L | H | L | H |
| 230-b | H | H | H | H | H |
| 230-c | H | H | H | H | H |
| 230-d | H | H | H | H | H |

The memory apparatus may sample the alignment command over one or more command intervals 225. Accordingly, based on which clock phase signal 220 samples a low state, the memory apparatus may determine a phase offset between the intermediate clock signal 215 and the host system clock signal 205. For example, if the host system clock signal 205 and the intermediate clock signal 215 are aligned (e.g., if the phase relationship is “0”), then the memory apparatus may identify that the value obtained over the CA1 pin as “LHHH.” Similarly, if the memory apparatus identifies that the value obtained over the CA1 pin is “HLHH,” then the memory apparatus may determine that the phase relationship is “1.” If the memory apparatus identifies that the value obtained over the CA1 pin is “HHLH,” then the memory apparatus may determine that the phase relationship is “2.” If the memory apparatus identifies that the value obtained over the CA1 pin is “HHHL,” then the memory apparatus may determine that the phase relationship is “3.”

The memory apparatus and/or the host system may use this phase relationship to align the intermediate clock signal 215 and/or the strobe signal with the host system clock signal 205. For example, the memory apparatus may adjust the base clock signal 210 and/or the intermediate clock signal 215 to align the rising edge of the clock phase signal 220-a with the rising edge of the clock cycle 230-a. Additionally, or alternatively, the memory apparatus may adjust the strobe signal to align the rising edge of an initial phase of the strobe signal with the rising edge of the clock cycle 230-a.

In some examples, the host system and/or the memory apparatus may perform a multiple pass training procedure to account for misalignment in a strobe signal due to the alignment command. For example, the host system may perform a coarse training procedure to obtain one or more coarse signaling parameters used to communicate signals between the host system and the memory apparatus. The one or more coarse signaling parameters may include one or more approximately uniform timing intervals for a strobe signal. After the coarse training procedure, the host system may communicate (e.g., using the one or more coarse signaling parameters) an alignment command to identify the phase relationship between the host system clock signal 205 and the intermediate clock signal 215. After communicating the alignment command, the host system may perform a fine training procedure to identify one or more fine signaling parameters. The fine training procedure may include independently adjusting the timing intervals for clock phases, which may account for misalignments introduced by the alignment command.

As indicated above, FIG. 2 is provided as an example. Other examples may differ from what is described with regard to FIG. 2.

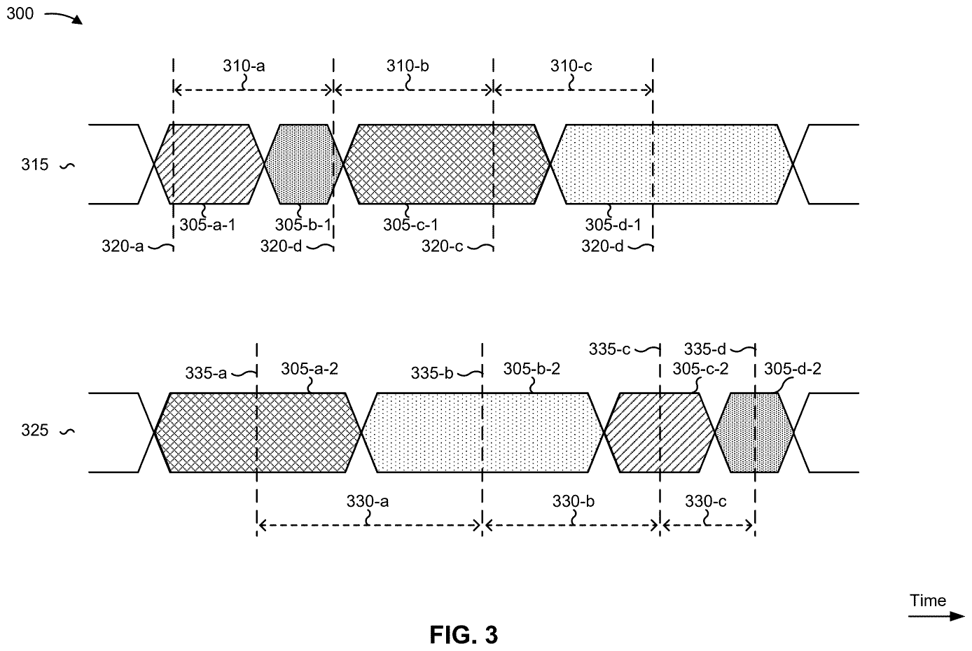

FIG. 3 is a diagram illustrating an example of a timing diagram 300 that supports multiple pass training procedures. The timing diagram 300 may illustrate timing aspects of signals communicated over and/or associated with one or more channels of an interface between a host system, such as the host system 105, and a memory apparatus, such as the memory system 110 and/or a memory device 120. For example, the timing diagram 300 may illustrate signaling communicated from the memory apparatus to the host system (e.g., as part of a read command). The signaling may include one or more data eyes 305. A data eye 305 may represent possible voltage levels of a pin (e.g., a pin of a data bus of the host interface 140) during a clock cycle 230.

To decode a data eye 305 transmitted over a data pin, the host system and/or the memory apparatus may use one or more strobe signals. A strobe signal may be a clock signal (e.g., a multi-phase clock signal) provided by the host system and/or the memory apparatus. In some examples, the interface between the host system and the memory apparatus may include a pin used to communicate the strobe signal, such as a data strobe pin. By way of illustrative example, as part of a read operation, the memory apparatus may generate a read strobe signal and may transmit the read strobe signal via the data strobe pin. The host system may sample the signal of the data pin at one or more rising edges of the read strobe signal. Similarly, as part of a write operation, the host system may generate a write strobe signal and may transmit the write strobe signal via the data strobe pin. The memory apparatus may sample the signal of the data pin at one or more rising edges of the write strobe signal. Accordingly, a strobe signal having rising edges at or near the respective centers of data eyes 305 may improve the ability of the host system and/or the memory apparatus to accurately decode the signal on the data pin.

In some implementations, the host system and/or the memory apparatus may modify a strobe signal to improve the ability of the memory apparatus and/or the host system to accurately decode the signal on the data pin. For example, the host system and/or the memory apparatus may add one or more strobe delays, which may also be referred to as strobe offsets, to particular phases of the strobe signal to shift the position of a particular rising edge.

To improve the positions of rising edges of a strobe signal (e.g., to increase the likelihood of a rising edge being at or near the center of a corresponding data eye 305), the host system and/or the memory apparatus may perform multiple training procedures. As described herein, a training procedure is a sequence of steps executed by the host system and/or the memory apparatus to determine one or more strobe offsets (e.g., strobe delays) for a strobe signal. The host system and/or the memory apparatus may store one or more values that indicate the one or more strobe offsets, and may use the one or more values as part of performing access operations (e.g., as part of communicating signals between the host system and the memory apparatus over an interface). In some examples, the host system and/or the memory apparatus may perform such training procedures during a training mode, such as a training mode initiated during and/or as a result of an initiation procedure of the host system and/or the memory apparatus.

For example, the host system may perform a coarse training procedure for the memory apparatus. The coarse training procedure may determine an approximately uniform set of timing intervals 310 for one or more strobe signals. As described herein, a timing interval is the amount of time (e.g., the duration) between successive rising edges of a strobe signal. Accordingly, an approximately uniform set of timing intervals 310 may indicate that the durations between respective rising edges of a strobe signal are approximately equal to each other.

The coarse training procedure may include providing one or more commands to the memory apparatus using the command/address bus. In some examples, the host system may provide a strobe signal to assist the memory apparatus in interpreting the one or more commands. Additionally, or alternatively, the host system may use an estimated delay (e.g., an estimated latency between the host system providing a signal and the memory apparatus interpreting the signal) to assist the memory apparatus in interpreting the one or more commands. In such examples, the memory apparatus may use one or more phases of a clock signal (e.g., the clock phase signals 220) to interpret the command. The one or more commands may include respective bit sequences. In some implementations, the one or more bit sequences may be relatively simple. For example, the one or more bit sequences may include a bit sequence “0111,” a bit sequence “1011,” a bit sequence “1101,” and/or a bit sequence “1110.”

The memory apparatus may decode the one or more commands to obtain one or more decoded bit sequences. The memory apparatus may transmit the decoded bit sequences back to the host system using one or more data pins. For example, the memory apparatus may transmit each bit of a decoded bit sequence using a respective data eye 305 over an interval 315. Additionally, the memory apparatus may provide a strobe signal (e.g., using a data strobe pin). The host system and/or the memory system may iteratively adjust the positions of the rising edges of the strobe signal (e.g., by adding one or more strobe offsets to the strobe signal) to identify one or more strobe offsets that result in the memory system accurately decoding and providing the one or more bit sequences (e.g., one or more strobe offsets that cause a particular bit sequence provided by the host system to be equal to the corresponding decoded bit sequence provided by the memory apparatus).

For example, the host system may determine a size of a timing interval 310 and/or a phase offset such that the rising edge 320-a falls within the data eye 305-a-1, the rising edge 320-b falls within the data eye 305-b-1, the rising edge 320-c falls within the data eye 305-c-1, and the rising edge 320-d falls within the data eye 305-d-1. Because the host system may be configured to determine approximately uniform timing intervals 310, the timing interval 310-a, the timing interval 310-b, and the timing interval 310-c may be approximately equal to each other.

In some implementations, after performing the coarse training procedure, the host system may issue an alignment command. As described in greater detail elsewhere herein, the alignment command may shift the phase of one or more memory apparatus clock signals. In some implementations, duty cycle distortion (e.g., changes in the of data eyes 305) may also shift, as illustrated in FIG. 3. For example, the interval 325 may illustrate a shift in phase of the memory apparatus clock signal after an alignment command, relative to the interval 315. Accordingly, using the position of the rising edges 320 to attempt to decode data eyes 305 within the interval 325 may result in misalignment errors.

To address these misalignment errors, the host system may perform a fine training procedure after issuing the alignment command. The fine training procedure may determine respective timing intervals 330 for respective phases of a strobe signal. Said another way, the fine training procedure may modify each phase of the strobe signal independently, such that the timing intervals 330 between successive rising edges 335 of the strobe signal may not necessarily be equal.

The fine training procedure may include providing one or more commands to the memory apparatus (e.g., using the command/address bus). The one or more commands may indicate that the memory apparatus is to provide relatively complex bit sequences to the host system. For example, the one or more commands may include respective pseudorandom binary sequences (PRBS) or other bit sequences configured to stress the signal integrity and timing of the host interface 140.

Similar to the coarse training procedure, the host system and/or the memory apparatus may iteratively adjust the position of the rising edges 335 of the strobe signal (e.g., by adding one or more strobe offsets to respective phases of the strobe signal) to identify one or more strobe offsets that result in the memory system accurately decoding and providing the one or more bit sequences. For example, the host system may iteratively shift positions of the rising edges 335. As part of an iteration, the host system may evaluate the accuracy of the bit sequence received from the memory apparatus and adjust the position of the rising edges 335 accordingly.

In some examples, the host system may adjust the position of the rising edges 335 independently. For example, the host system may identify a first phase offset for the rising edge 335-a such that the rising edge 335-a falls within the data eye 305-a-2. The host system may identify a second phase offset for the rising edge 335-b such that the rising edge 335-b falls within the data eye 305-b-2. The host system may identify a third phase offset for the rising edge 335-c such that the rising edge 335-c falls within the data eye 305-c-2. The host system may identify a fourth phase offset for the rising edge 335-d such that the rising edge 335-d falls within the data eye 305-d-2.

As indicated above, FIG. 3 is provided as an example. Other examples may differ from what is described with regard to FIG. 3.

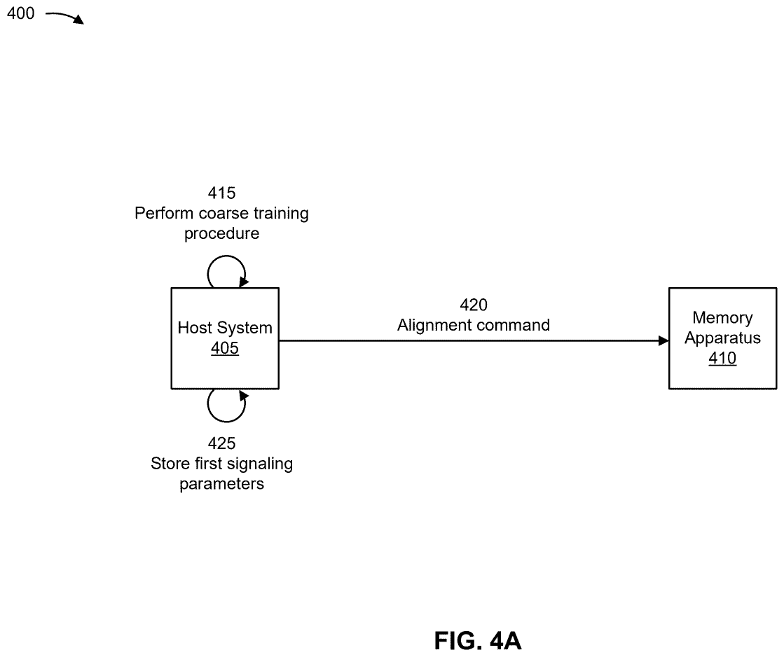

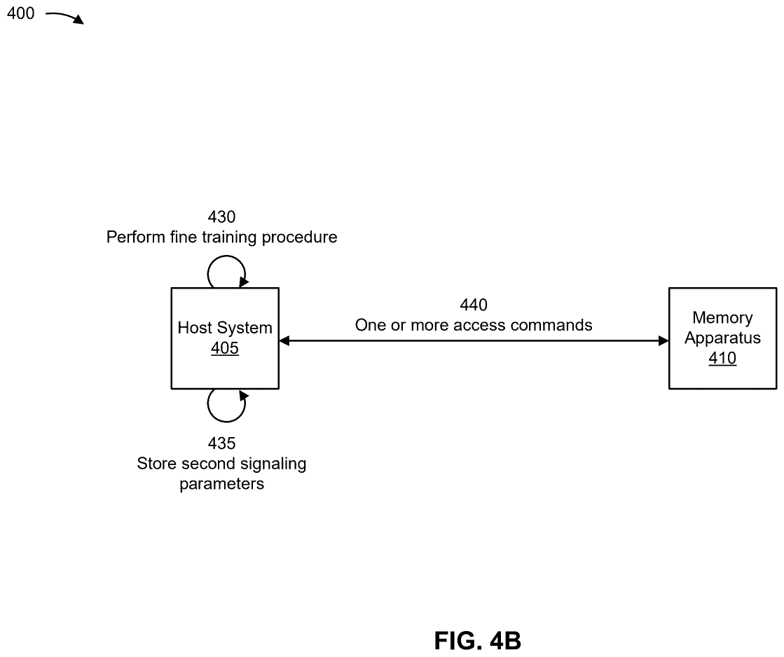

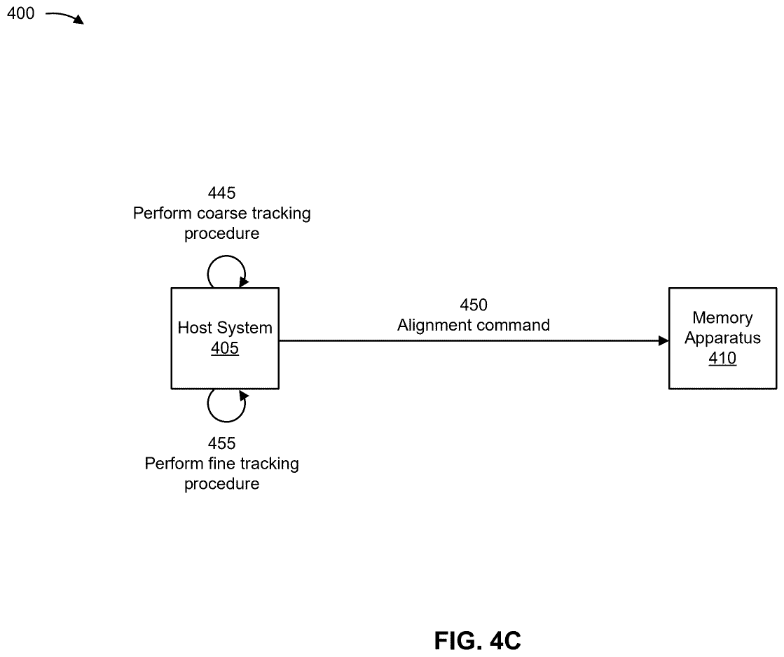

FIGS. 4A through 4C are diagrams of an example 400 of multiple pass training procedures. The operations described in connection with FIGS. 4A through 4C may be performed by the host system 105 and/or one or more components of the host system 105, such as the host processor 150 and/or the host interface 140. Additionally, or alternatively, the operations described in connection with FIGS. 4A through 4C may be performed by the memory system 110 and/or one or more components of the memory system 110, such as the memory system controller 115, one or more memory devices 120, and/or one or more local controllers 125.

As shown in FIGS. 4A through 4C, the example 400 may include a host system 405 and a memory apparatus 410. The host system 405 may be the host system 105. The memory apparatus 410 may be, or may include, the memory system 110, one or more memory devices 120, and/or one or more controllers (e.g., the memory system controller 115 and/or one or more local controllers 125).

As shown in FIG. 4A, and by reference number 415, the host system 405 may perform a coarse training procedure. Performing the coarse training procedure may include determining one or more coarse signaling parameters, such as one or more timing intervals and/or one or more strobe offsets for one or more strobe signals. As described in greater detail in connection with FIG. 3, to perform the coarse training procedure, the host system 405 may provide one or more commands to the memory apparatus 410 using the command/address bus. The one or more commands may include respective bit sequences. Additionally, the one or more commands may indicate that the memory apparatus 410 is to decode the bit sequences and provide one or more decoded bit sequences to the host system 405.

The memory apparatus 410 may decode the one or more commands to obtain the one or more decoded bit sequences. The memory apparatus 410 may transmit the decoded bit sequences to the host system 405 using one or more data pins. Additionally, the memory apparatus 410 may provide a strobe signal (e.g., using a data strobe pin). The host system 405 and/or the memory apparatus 410 may iteratively adjust the positions of rising edges of the strobe signal (e.g., by adding one or more strobe offsets to the strobe signal) to identify one or more strobe offsets that result in the memory apparatus 410 accurately decoding and providing the one or more bit sequences.

In some implementations, as shown by reference number 420, the host system 405 may store the one or more coarse signaling parameters. For example, the host system 405 may store one or more values indicating the one or more coarse signaling parameters, such as by storing the one or more values to configuration registers or other storage locations within the host system 405. The host system 405 may reference these values during subsequent training procedures and/or access operations.

As shown by reference number 425, the host system 405 may provide, and the memory apparatus 410 may obtain, an alignment command. The alignment command may indicate that the memory apparatus 410 is to determine a phase relationship between the host system clock signal and the memory apparatus clock signal. Based on, in response to, or otherwise associated with obtaining the alignment command, the memory apparatus 410 may identify the phase relationship. In some examples, the memory apparatus 410 may modify one or more clock signals, such as an intermediate clock signal 215 and/or a strobe signal, based on the phase relationship.

In some implementations, the host system 405 may use the one or more coarse signaling parameters to provide the alignment command. For example, the host system 405 may reference the stored coarse signaling parameters to determine a timing at which the alignment command may be issued. By using the coarse signaling parameters, the host system 405 may improve the ability of the memory apparatus 410 to obtain and decode the alignment command.

As shown in FIG. 4B, and by reference number 430, the host system 405 may perform a fine training procedure. To perform the fine training procedure, the host system 405 may determine respective timing intervals for respective phases of a strobe signal. Said another way, the host system 405 may modify each phase of the strobe signal independently, such that the timing intervals between successive rising edges of the strobe signal may not necessarily be equal.

The host system 405 may provide one or more commands to the memory apparatus 410 (e.g., using the command/address bus). The one or more commands may indicate that the memory apparatus 410 is to provide relatively complex bit sequences to the host system 405. For example, the one or more commands may include respective PRBSs or other bit sequences configured to stress the signal integrity and timing of the host interface 140. The host system 405 and/or the memory apparatus 410 may iteratively adjust the position of the rising edges of the strobe signal (e.g., by adding one or more strobe offsets to respective phases of the strobe signal) to identify one or more strobe offsets that result in the memory apparatus 410 accurately decoding and providing the one or more bit sequences. For example, the host system 405 may iteratively shift positions of the rising edges. As part of an iteration, the host system 405 may evaluate the accuracy of the bit sequence received from the memory apparatus 410 and adjust the position of the rising edges accordingly.

In some implementations, as shown by reference number 435, the host system 405 may store the one or more fine signaling parameters. For example, the host system 405 may store one or more values indicating the one or more fine signaling parameters, such as by storing the one or more values to configuration registers or other storage locations within the host system 405. The host system 405 may reference these values during subsequent training procedures and/or access operations.

As shown by reference number 440, the host system 405 and/or the memory apparatus 410 may perform one or more access commands using the one or more fine training parameters. For example, the host system 405 may provide, and the memory apparatus 410 may obtain, the one or more access commands. By way of illustrative example, the one or more access commands may indicate a read operation to communicate data from the memory apparatus 410 to the host system 405. As part of providing the data, the memory apparatus 410 may provide a strobe signal to the host system 405. The host system 405 and/or the memory apparatus 410 may modify the strobe signal using the one or more fine training parameters (e.g., by adjusting the strobe signal using one or more strobe offsets).

In some implementations, the host system 405 and/or the memory apparatus 410 may adjust signaling parameters as part of a tracking phase of operation. A tracking phase of operation may include one or more procedures (e.g., one or more tracking procedures) to adjust signaling parameters outside of a training mode and/or an initialization mode. In some implementations, the host system 405 and/or the memory apparatus 410 may initiate a tracking procedure based on a reset of a clock signal, such as the host system clock signal. For example, the host system 405 and/or the memory apparatus 410 may detect a reset in the host system clock signal. Based on, in response to, or otherwise associated with detecting the reset, the host system 405 and/or the memory apparatus 410 may initiate the tracking procedure. Additionally, or alternatively, based on, in response to, or otherwise associated with detecting the reset, the host system 405 and/or the memory apparatus 410 may issue another alignment command to identify another phase relationship caused by the reset.

For example, as shown in FIG. 4C, and by reference number 445, the host system 405 may perform a coarse tracking procedure. Performing the coarse tracking procedure may include determining one or more other coarse signaling parameters, such as one or more timing intervals and/or one or more strobe offsets for one or more strobe signals. Similar to the coarse training procedure, to perform the coarse tracking procedure, the host system 405 may provide one or more commands to the memory apparatus 410 using the command/address bus. The one or more commands may include respective bit sequences. Additionally, the one or more commands may indicate that the memory apparatus 410 is to decode the bit sequences and provide one or more decoded bit sequences to the host system 405.

The memory apparatus 410 may decode the one or more commands to obtain the one or more decoded bit sequences. The memory apparatus 410 may transmit the decoded bit sequences to the host system 405 using one or more data pins. Additionally, the memory apparatus 410 may provide a strobe signal (e.g., using a data strobe pin). The host system 405 and/or the memory apparatus 410 may iteratively adjust the positions of rising edges of the strobe signal (e.g., by adding one or more strobe offsets to the strobe signal) to identify one or more strobe offsets that result in the memory apparatus 410 accurately decoding and providing the one or more bit sequences.

In some implementations, the host system 405 may store the one or more other coarse signaling parameters. For example, the host system 405 may store one or more values indicating the one or more other coarse signaling parameters, such as by storing the one or more values to configuration registers or other storage locations within the host system 405. The host system 405 may reference these values during subsequent training procedures and/or access operations.

As shown by reference number 450, the host system 405 may provide, and the memory apparatus 410 may obtain, another alignment command. The other alignment command may indicate that the memory apparatus 410 is to determine another phase relationship between the host system clock signal and the memory apparatus clock signal. Based on, in response to, or otherwise associated with obtaining the other alignment command, the memory apparatus 410 may identify the other phase relationship. In some examples, the memory apparatus 410 may modify one or more clock signals, such as an intermediate clock signal 215 and/or a strobe signal, based on the other phase relationship.

As shown by reference number 455, the host system 405 may perform a fine tracking procedure. Similar to the fine training procedure, to perform the fine tracking procedure, the host system 405 may determine respective timing intervals for respective phases of a strobe signal. Said another way, the host system 405 may modify each phase of the strobe signal independently, such that the timing intervals between successive rising edges of the strobe signal may not necessarily be equal.

The host system 405 may provide one or more commands to the memory apparatus 410 (e.g., using the command/address bus). The one or more commands may indicate that the memory apparatus 410 is to provide relatively complex bit sequences to the host system 405. For example, the one or more commands may include respective PRBSs or other bit sequences configured to stress the signal integrity and timing of the host interface 140. The host system 405 and/or the memory apparatus 410 may iteratively adjust the position of the rising edges of the strobe signal (e.g., by adding one or more strobe offsets to respective phases of the strobe signal) to identify one or more strobe offsets that result in the memory apparatus 410 accurately decoding and providing the one or more bit sequences. For example, the host system 405 may iteratively shift positions of the rising edges. As part of an iteration, the host system 405 may evaluate the accuracy of the bit sequence received from the memory apparatus 410 and adjust the position of the rising edges accordingly.

In some implementations, the host system 405 may store the one or more other fine signaling parameters. For example, the host system 405 may store one or more values indicating the one or more other fine signaling parameters, such as by storing the one or more values to configuration registers or other storage locations within the host system 405. The host system 405 may reference these values during subsequent training procedures and/or access operations.

As indicated above, FIGS. 4A through 4C are provided as examples. Other examples may differ from what is described with regard to FIGS. 4A through 4C.

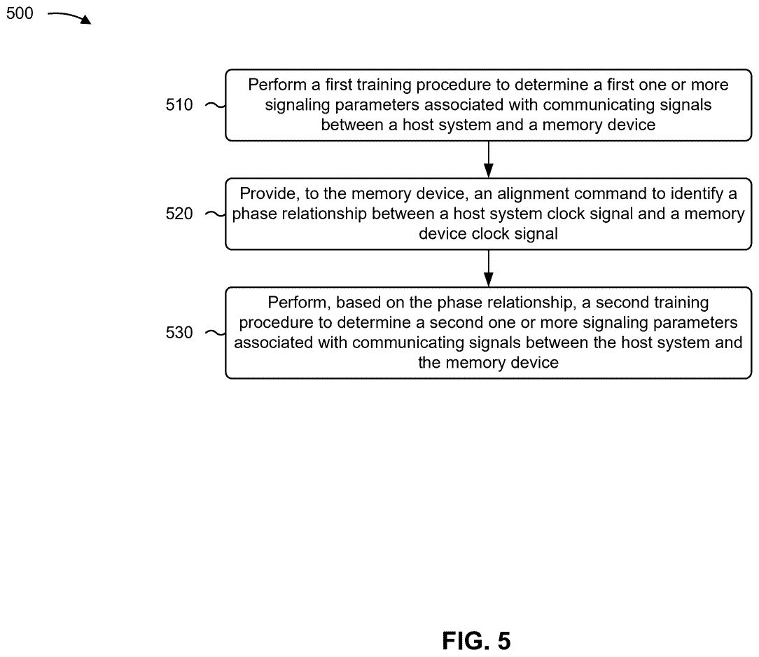

FIG. 5 is a flowchart of an example method 500 associated with multiple pass training procedures. In some implementations, a host system (e.g., the host system 105) may perform or may be configured to perform the method 500. In some implementations, another device or a group of devices separate from or including the host system (e.g., the memory system 110, the memory system controller 115, one or more memory devices 120, one or more local controllers 125, one or more memory arrays 130, one or more volatile memory arrays 135, the host interface 140, and/or one or more memory interfaces 145) may perform or may be configured to perform the method 500. Additionally, or alternatively, one or more components of the host system (e.g., the host processor 150) may perform or may be configured to perform the method 500. Thus, means for performing the method 500 may include the host system and/or one or more components of the host system. Additionally, or alternatively, a non-transitory computer-readable medium may store one or more instructions that, when executed by the host system, cause the host system to perform the method 500.

As shown in FIG. 5, the method 500 may include performing a first training procedure to determine a first one or more signaling parameters associated with communicating signals between the host system and a memory device (block 510). As further shown in FIG. 5, the method 500 may include providing, to the memory device, an alignment command to identify a phase relationship between a host system clock signal and a memory apparatus clock signal (block 520). As further shown in FIG. 5, the method 500 may include performing, based on the phase relationship, a second training procedure to determine a second one or more signaling parameters associated with communicating signals between the host system and the memory device (block 530).

The method 500 may include additional aspects, such as any single aspect or any combination of aspects described below and/or described in connection with one or more other methods or operations described elsewhere herein.

In a first aspect, performing the first training procedure comprises determining an approximately uniform set of timing intervals for one or more strobe signals, wherein the first one or more signaling parameters comprise the approximately uniform set of timing intervals.

In a second aspect, alone or in combination with the first aspect, performing the second training procedure comprises determining respective timing intervals of a set of timing intervals for one or more strobe signals, wherein the second one or more signaling parameters comprise the set of timing intervals.

Although FIG. 5 shows example blocks of a method 500, in some implementations, the method 500 may include additional blocks, fewer blocks, different blocks, or differently arranged blocks than those depicted in FIG. 5. Additionally, or alternatively, two or more of the blocks of the method 500 may be performed in parallel. The method 500 is an example of one method that may be performed by one or more devices described herein. These one or more devices may perform or may be configured to perform one or more other methods based on operations described herein.

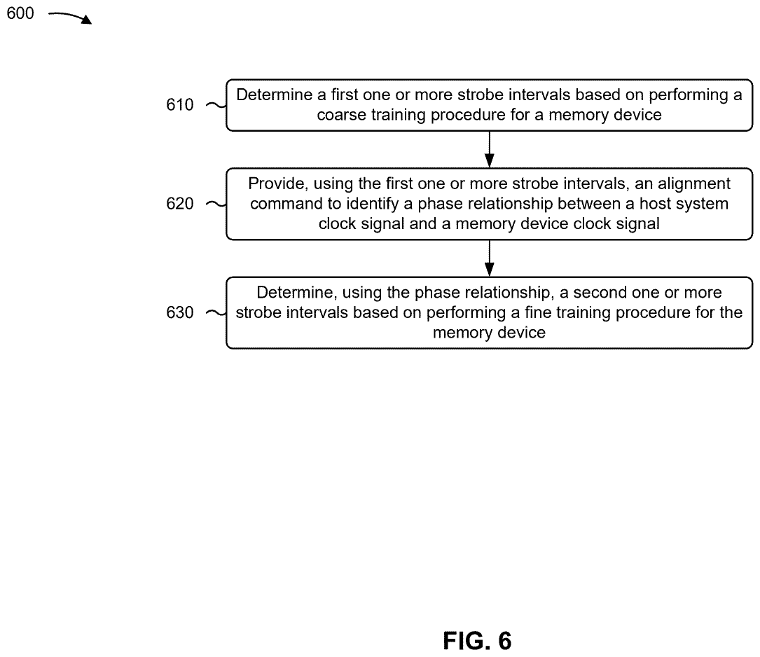

FIG. 6 is a flowchart of an example method 600 associated with multiple pass training procedures. In some implementations, a host system (e.g., the host system 105) may perform or may be configured to perform the method 600. In some implementations, another device or a group of devices separate from or including the host system (e.g., the memory system 110, the memory system controller 115, one or more memory devices 120, one or more local controllers 125, one or more memory arrays 130, one or more volatile memory arrays 135, the host interface 140, and/or one or more memory interfaces 145) may perform or may be configured to perform the method 600. Additionally, or alternatively, one or more components of the host system (e.g., the host processor 150) may perform or may be configured to perform the method 600. Thus, means for performing the method 600 may include the host system and/or one or more components of the host system. Additionally, or alternatively, a non-transitory computer-readable medium may store one or more instructions that, when executed by the host system, cause the host system to perform the method 600.

As shown in FIG. 6, the method 600 may include determining a first one or more strobe intervals based on performing a coarse training procedure for a memory device (block 610). As further shown in FIG. 6, the method 600 may include providing, using the first one or more strobe intervals, an alignment command to identify a phase relationship between a host system clock signal and a memory apparatus clock signal (block 620). As further shown in FIG. 6, the method 600 may include determining, using the phase relationship, a second one or more strobe intervals based on performing a fine training procedure for the memory device (block 630).

The method 600 may include additional aspects, such as any single aspect or any combination of aspects described below and/or described in connection with one or more other methods or operations described elsewhere herein.

In a first aspect, the first one or more strobe intervals are approximately uniform.

In a second aspect, alone or in combination with the first aspect, the method 600 includes determining respective offsets to the first one or more strobe intervals based on independently adjusting the first one or more strobe intervals, wherein the second one or more strobe intervals are based on the respective offsets.

Although FIG. 6 shows example blocks of a method 600, in some implementations, the method 600 may include additional blocks, fewer blocks, different blocks, or differently arranged blocks than those depicted in FIG. 6. Additionally, or alternatively, two or more of the blocks of the method 600 may be performed in parallel. The method 600 is an example of one method that may be performed by one or more devices described herein. These one or more devices may perform or may be configured to perform one or more other methods based on operations described herein.

In some implementations, a system includes a host system configured to: perform a first training procedure to determine a first one or more signaling parameters associated with communicating signals between the host system and a memory device; provide, to the memory device, an alignment command to identify a phase relationship between a host system clock signal and a memory apparatus clock signal; and perform, based on the phase relationship, a second training procedure to determine a second one or more signaling parameters associated with communicating signals between the host system and the memory device.

In some implementations, a system includes a host system configured to: determine a first one or more strobe intervals based on performing a coarse training procedure for a memory device; provide, to the memory device and using the first one or more strobe intervals, an alignment command to identify a phase relationship between a host system clock signal and a memory apparatus clock signal; and determine, using the phase relationship, a second one or more strobe intervals based on performing a fine training procedure for the memory device.

In some implementations, a method includes performing, by a host system, a first training procedure to determine a first one or more signaling parameters associated with communicating signals between the host system and a memory device; providing, by the host system and to the memory device, an alignment command to identify a phase relationship between a host system clock signal and a memory apparatus clock signal; and performing, based on the phase relationship, a second training procedure to determine a second one or more signaling parameters associated with communicating signals between the host system and the memory device.

In some implementations, a method includes determining, by a host system, a first one or more strobe intervals based on performing a coarse training procedure for a memory device; providing, by the host system to the memory device and using the first one or more strobe intervals, an alignment command to identify a phase relationship between a host system clock signal and a memory apparatus clock signal; and determining, using the phase relationship, a second one or more strobe intervals based on performing a fine training procedure for the memory device.

The foregoing disclosure provides illustration and description but is not intended to be exhaustive or to limit the implementations to the precise forms disclosed. Modifications and variations may be made in light of the above disclosure or may be acquired from practice of the implementations described herein.

As used herein, the terms “substantially” and “approximately” mean “within reasonable tolerances of manufacturing and measurement.”

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

When “a component” or “one or more components” (or another element, such as “a controller” or “one or more controllers”) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A system, comprising:
a host system configured to:
perform a first training procedure to determine a first one or more signaling parameters associated with communicating signals between the host system and a memory device;
provide, to the memory device, an alignment command to identify a phase relationship between a host system clock signal and a memory apparatus clock signal; and
perform, based on the phase relationship, a second training procedure to determine a second one or more signaling parameters associated with communicating signals between the host system and the memory device.

2. The system of claim 1, wherein, to perform the first training procedure, the host system is configured to:
determine an approximately uniform set of timing intervals for one or more strobe signals, wherein the first one or more signaling parameters comprise the approximately uniform set of timing intervals.

3. The system of claim 1, wherein, to perform the second training procedure, the host system is configured to:
determine respective timing intervals of a set of timing intervals for one or more strobe signals, wherein the second one or more signaling parameters comprise the set of timing intervals.

4. The system of claim 3, wherein, to determine the respective timing intervals, the host system is configured to:
determine respective offsets to the first one or more signaling parameters based on independently adjusting the first one or more signaling parameters, wherein the respective timing intervals are based on the respective offsets.

5. The system of claim 1, wherein the memory apparatus clock signal comprises a multi-phase clock signal.

6. The system of claim 1, wherein the host system is further configured to:
perform, as part of a tracking phase of operation, a first tracking procedure to determine a third one or more signaling parameters associated with communicating signals between the host system and the memory device;
provide, to the memory device and as part of the tracking phase of operation, another alignment command to identify another phase relationship between the host system clock signal and the memory apparatus clock signal; and
perform, as part of the tracking phase of operation and based on the other phase relationship, a second tracking procedure to determine a fourth one or more signaling parameters associated with communicating signals between the host system and the memory device.

7. The system of claim 6, wherein the host system is further configured to:
detect a reset of the host system clock signal, wherein the host system provides the other alignment command in response to detecting the reset.

8. The system of claim 1, wherein the phase relationship comprises a value indicating a phase offset between a first initial phase of the host system clock signal and a second initial phase of a memory apparatus clock signal of the memory apparatus clock signal.

9. The system of claim 1, wherein the host system is further configured to provide the alignment command after performing the first training procedure, and wherein the host system is further configured to perform the second training procedure after providing the alignment command.

10. The system of claim 1, wherein the host system is further configured to:
store one or more values indicating the one or more second signaling parameters; and
perform one or more access commands using the one or more second signaling parameters.

11. The system of claim 1, wherein the alignment command comprises a command start point (CSP) command.

12. A system, comprising:
a host system configured to:
determine a first one or more strobe intervals based on performing a coarse training procedure for a memory device;
provide, to the memory device and using the first one or more strobe intervals, an alignment command to identify a phase relationship between a host system clock signal and a memory apparatus clock signal; and
determine, using the phase relationship, a second one or more strobe intervals based on performing a fine training procedure for the memory device.

13. The system of claim 12, wherein the first one or more strobe intervals are approximately uniform.

14. The system of claim 12, wherein, to determine the second one or more strobe intervals, the host system is configured to:
determine respective offsets to the first one or more strobe intervals based on independently adjusting the first one or more strobe intervals, wherein the second one or more strobe intervals are based on the respective offsets.

15. The system of claim 12, wherein the memory apparatus clock signal comprises a multi-phase clock signal.

16. The system of claim 12, wherein the host system is further configured to:
determine a third one or more strobe intervals based on performing a coarse tracking procedure for the memory device;
provide, to the memory device, another alignment command to identify another phase relationship between the host system clock signal and the memory apparatus clock signal; and
determine, using the other phase relationship, a fourth one or more strobe intervals based on performing a fine tracking procedure for the memory device.

17. The system of claim 16, wherein the host system is further configured to:
detect a reset of the host system clock signal, wherein the host system provides the other alignment command in response to detecting the reset.

18. The system of claim 12, wherein the phase relationship comprises a value indicating a phase offset between a first initial phase of the host system clock signal and a second initial phase of a memory apparatus clock signal of the memory apparatus clock signal.

19. The system of claim 12, wherein the host system is further configured to:
store one or more values indicating the second one or more strobe intervals; and
perform one or more access commands using the second one or more strobe intervals.

20. A method, comprising:
performing, by a host system, a first training procedure to determine a first one or more signaling parameters associated with communicating signals between the host system and a memory device;
providing, by the host system and to the memory device, an alignment command to identify a phase relationship between a host system clock signal and a memory apparatus clock signal; and
performing, based on the phase relationship, a second training procedure to determine a second one or more signaling parameters associated with communicating signals between the host system and the memory device.

21. The method of claim 20, wherein performing the first training procedure comprises:
determining an approximately uniform set of timing intervals for one or more strobe signals, wherein the first one or more signaling parameters comprise the approximately uniform set of timing intervals.

22. The method of claim 20, wherein performing the second training procedure comprises:
determining respective timing intervals of a set of timing intervals for one or more strobe signals, wherein the second one or more signaling parameters comprise the set of timing intervals.

23. A method, comprising:
determining, by a host system, a first one or more strobe intervals based on performing a coarse training procedure for a memory device;
providing, by the host system to the memory device and using the first one or more strobe intervals, an alignment command to identify a phase relationship between a host system clock signal and a memory apparatus clock signal; and
determining, using the phase relationship, a second one or more strobe intervals based on performing a fine training procedure for the memory device.

24. The method of claim 23, wherein the first one or more strobe intervals are approximately uniform.

25. The method of claim 23, determining the second one or more strobe intervals comprises:
determining respective offsets to the first one or more strobe intervals based on independently adjusting the first one or more strobe intervals, wherein the second one or more strobe intervals are based on the respective offsets.
